(19) United States
(12) Patent Application Publication
(10) Pub. No.: US 2001/0052392 A1
(43) Pub. Date: Dec. 20, 2001

(54) MULTICHAMBER SUBSTRATE PROCESSING APPARATUS

(76) Inventors: MASAHIKO NAKAMURA, TOKYO (JP); YUKIHITO TASHIRO, TOKYO (JP); MASAHITO ISHIHARA, TOKYO (JP); NOBUYUKI TAKAHASHI, TOKYO (JP)

Correspondence Address: BURNS DOANE SWECKER & MATHIS L L P, POST OFFICE BOX 1404, ALEXANDRIA, VA, 22313-1404, US

(21) Appl. No.: 09/219,453

(22) Filed: Dec. 23, 1998

(30) Foreign Application Priority Data
Feb. 25, 1998 (JP) 10-60670

(51) Int. Cl. H01L 21/00

(52) U.S. Cl. 156/345; 118/729

(57) ABSTRACT

A multichamber substrate processing apparatus in which substrates are always positioned accurately at set positions inside a process chamber is a practical apparatus that affords excellent productivity while occupying little space. A heating chamber 6 for heating a substrate Sb before a film is deposited in a sputtering chamber 8 and a CVD chamber 9 is provided with an alignment means for performing center alignment whereby the position of the center of the substrate Sb is calculated and the substrate is centered over a preset position, and for performing circumferential alignment whereby the circumferential position of the substrate Sb is calculated and this circumferential position is aligned with a preset position. Alignment is accomplished by a process in which the substrate Sb is lifted by a lifting mechanism 65 from a substrate holder 62 containing a built-in heater 621 to a detection line, and the extent to which light from a photoemitter 671 is blocked by the points along the edge of the substrate Sb is sensed by a photodetector 672 while the substrate Sb is rotated in this position by a rotating mechanism 64.

### BACKGROUND OF THE APPLICATION

1. Technical Field to Which the Invention Belongs

The subject invention relates to a substrate processing apparatus for use in the manufacture of electronic devices such as semiconductor integrated circuits, and more particularly to a multichamber-type substrate processing apparatus equipped with a plurality of process chambers.

2. Discussion of Related Art

Various substrate processings are often performed during the manufacture of semiconductor integrated circuits. For example, such processings are often performed by sputtering or chemical vapor deposition (CVD) during the manufacture of electroconductive films for interconnecting. Etching is often used to form interconnecting patterns.

Multichamber-type substrate processing apparatus are known as such substrate processing apparatus. FIG. 14 is a schematic plan view depicting a conventional multichamber-type substrate processing apparatus (hereinafter referred to as “a multichamber substrate processing apparatus”). The multichamber substrate processing apparatus comprises a centrally located separation chamber 1, and a plurality of process chambers 2 disposed together with a pair of load lock chambers 3 around the separation chamber 1.

Each process chamber 2 and the two load lock chambers 3 are airtightly connected to the separation chamber 1. Gate valves (not shown) are provided at the borders between the separation chamber 1 and the process chambers 2 and load lock chambers 3. Each chamber is pumped down to the desired pressure with the aid of a dedicated pumping system (not shown).

The separation chamber 1 prevents mutual contamination of the atmosphere inside the process chambers 2 and serves as a space for transferring substrates to the process chambers 2 and load lock chambers 3. A transfer robot 11 for transferring the substrates Sb between chambers is disposed inside the separation chamber 1.

In-lock cassettes 31 for storing a prescribed number of substrates Sb are disposed inside each load lock chamber 3. The transfer robot 11 retrieves individual substrates Sb from the in-lock cassette 31 inside a load lock chamber 3 and sequentially transfers them to each process chamber 2. The substrates Sb are gradually treated in the process chambers 2. The processed substrates Sb are transferred by the transfer robot 11 to the initial load lock chamber 3 or to another load lock chamber 3. The substrates Sb thus processed are stored in the in-lock cassettes 31.

Autoloaders 4 for transferring the substrates Sb are provided between the in-lock cassettes 31 and external cassettes 41, which are disposed on the atmospheric side. Each autoloader 4 comprises holding fingers 42 for holding a single substrate Sb, and moving mechanisms 43 for moving the holding fingers 42.

Articulated robots provided with arms capable of rotating around vertical axis of rotation are often used for the moving mechanisms 43. These moving mechanisms 43 can move substrates Sb in the radial direction (redirection) of rotation of the arm, in the axial direction (z-direction), and in the rotational direction (θ-direction).

With such a moving mechanism 43, the autoloader 4 retrieves individual substrates Sb from the external cassette 41 and stores them in the in-lock cassette 31 in either load lock chamber 3. Each load lock chamber 3 is provided with a gate valve (not shown) for opening and closing the device during the admittance and retrieval of substrates Sb to and from the atmospheric side. When this gate valve is open, the gate valve on the border with the separation chamber 1 is closed.

A requirement of the conventional multichamber substrate processing apparatus is that the substrates Sb be introduced into each process chamber 2 at the same position. This is because problems in terms of process reproducibility commonly arise if the substrates Sb are not always processed at the same position inside the process chambers 2.

The substrates Sb are processed after being mounted on the upper surface of the platform-shaped substrate holders disposed inside the process chambers 2. During film deposition, thin films are deposited even in those surface areas of the substrate holders which are not covered by substrates Sb. Shifting a substrate Sb away from its mounting position places this substrate Sb over an unneeded thin film deposited as a result of the aforementioned film deposition. The result is that particles (dust particles) separated from this unneeded thin film adhere to the reverse side of the substrate Sb.

In the case of etching, an etching-resistant surface treatment is performed on the surface areas of a substrate holder other than those on which the substrate Sb is supported. However, in view of the resulting heat contact properties, such surface treatments are not performed on the areas covered by the substrate Sb. Consequently, shifting the substrate Sb away from its mounting position exposes the portions that have not been surface-treated, causes the substrate holder to be etched, and undesirable particles to be formed.

The requirement that the substrate Sb always be disposed in the same position is complemented by the need to always maintain the same position in the circumferential direction (the same position in the rotational direction when the system is rotated around the center of the substrate Sb as an axis of rotation). This requirement generally stems from the need for process reproducibility. When, for example, the substrate Sb is a semiconductor wafer having an orientation flat, the substrate holder is provided with a depression that conforms to the shape of the substrate Sb, and the substrate is fitted into this depression. Any mismatch between the shape of the depression and the shape of the portion constituting the orientation flat prevents the substrate Sb from fitting into the depression and creates a transfer error.

Because of these requirements, it was necessary to endow conventional multichamber substrate processing apparatus with alignment functions such that a reference position was established, and the substrates Sb were centered over this reference position (these functions will hereinafter be referred to as “center alignment”), and that the corresponding position in the circumferential direction was aligned with a preset position (these functions will hereinafter be referred to as “circumferential alignment”).

As shown in FIG. 14, an alignment device 5 is disposed between the external cassettes 41 and the load lock chambers 3. FIG. 15 is a schematic oblique view depicting the alignment device 5 shown in FIG. 14.

The alignment device 5 has a stage 51 for mounting substrates Sb. The stage 51 is supported by a post 52. The post 52 is rotated by a rotating mechanism 53. The stage 51, post 52, and rotating mechanism 53 are integrated and supported on a support platform 54. The support platform 54 comprises an X-direction movement mechanism 55 for moving the platform in the X-direction, and a Y-direction movement mechanism 56 for moving the platform in the Y-direction. The position of the substrate Sb is sensed by a sensor (not shown). A control unit (not shown) controls the X-direction movement mechanism 55 and the Y-direction movement mechanism 56 in accordance with the signals from the sensor.

The stage 51 is a diskoid that is smaller than the substrate Sb. The holding fingers 42 are roughly U-shaped and have an inside width that is greater than the diameter of the stage 51. The stage 51 is disposed inside the U-shape of a holding finger 42 when a substrate Sb is mounted on the stage 51. At this time, the center of the holding finger 42 lies on the axis of rotation that passes vertically through the center of the stage 51.

To center a substrate Sb, it is determined to what degree the center of the substrate is shifted away from the point (hereinafter “the center of rotation”) in which the axis of rotation of the stage 51 passes through the surface of the substrate Sb, and the X-direction movement mechanism 55 and Y-direction movement mechanism 56 are actuated in order to center the substrate over the center of rotation.

The X-direction movement mechanism 55 and the Y-direction movement mechanism 56 are actuated based on the sensing results of a sensor (not shown). Sensor arrangements, while varying with the detection system, may be classified as those using a plurality of photosensors, and those using image sensors such as CCD sensors. In a multisensor arrangement, a plurality of photosensors are disposed uniformly along a circle that is slightly larger than the diameter of a substrate Sb whose center coincides with the axis of rotation.

When a substrate Sb is mounted on the stage 51, the rotating mechanism 53 rotates the stage 51 through the agency of the post 52. The substrate Sb rotates together with the rotation of the stage 51. During the rotation, the peripheral edge of the substrate Sb periodically blocks or exposes a plurality of photosensors in accordance with the shift between the center of rotation and the center of the substrate Sb. At this time, the shift between the center of rotation and the center of the substrate Sb can be determined by the known sequence and timing of blocked and exposed photosensors. A control unit (not shown) performs these calculations and determines the shift between the center of rotation and the center of the substrate Sb. The control unit sends out drive signals to the X-direction movement mechanism 55 and Y-direction movement mechanism 56 in order to correct this shift.

In a system using CCD sensors, the CCD sensors are arranged to capture images of certain areas along the peripheral edge of a substrate Sb. The CCD sensors are fixed in place, and the substrate Sb is rotated by the rotating mechanism 53. The images of the peripheral edge of the substrate Sb captured by the CCD sensors exhibit flutter in accordance with the shift between the center of rotation and the center of the substrate Sb. The shift between the center of rotation and the center of the substrate Sb can be determined by calculation on the basis of information about the amount of flutter and the rotation angle of the substrate Sb at which the flutter occurred. Based on this calculation, drive signals are issued by the control unit to the X-direction movement mechanism 55 and Y-direction movement mechanism 56, and the center of rotation and the center of the substrate Sb are aligned.

Information about the distance between a particular location (for example, an orientation flat) along the peripheral edge of the substrate Sb and about the angular distance serving as reference is also obtained by calculation on the basis of information about the amount of flutter and the rotation angle of the substrate Sb at which the flutter occurred. Based on the results of this calculation, the angular stage 51 is rotated, and the substrate Sb is aligned in the circumferential direction.

After such center alignment and circumferential alignment have been performed, a holding finger 42 removes the substrate Sb from the stage 51 and transfers this substrate Sb to the in-lock cassette 31 in a load lock chamber 3. Two autoloaders 4 are provided, as shown in FIGS. 14 and 15. These two autoloaders 4 are equipped with a single alignment device 5.

In the conventional multichamber substrate processing apparatus, an alignment device 5 is disposed between the external cassettes 41 and the load lock chambers 3. The provision of the alignment device 5 at this position widens the space between the external cassettes 41 and the load lock chambers 3 and extends the travel distance for the autoloaders 4. A drawback of the conventional multichamber substrate processing apparatus is the wide space occupied by the mechanism outside the load lock chambers 3.

In the conventional multichamber substrate processing apparatus, center alignment and circumferential alignment are performed while each substrate Sb is transferred from the external cassettes 41 to the load lock chambers 3. A long time is needed to perform such transfers in the conventional multichamber substrate processing apparatus. A resulting drawback of the conventional multichamber substrate processing apparatus is an extended lead time (total time from the moment a substrate Sb is introduced into the apparatus until the moment the substrate is recovered).

Center alignment or circumferential alignment must be performed immediately before the substrate Sb is processed in a process chamber 2. With the conventional multichamber substrate processing apparatus, however, such center alignment or circumferential alignment was performed some time before a processing was carried out in a process chamber 2. While being transferred to the treatment chamber 2 following center alignment or circumferential alignment, the substrate Sb will most likely be shifted away from the position set by such center alignment and circumferential alignment. If it is shifted during transfer, the substrate Sb will not be installed properly in the process chamber 2. The center alignment or circumferential alignment performed during transfer thus becomes ineffective. For example, the substrate Sb is shifted from its designated position inside the process chamber 2 if this substrate is shifted by an external factor while held by a holding finger 42 or the transfer robot 11 following center alignment and circumferential alignment.

### Objects and Summary

An object of the subject invention, which is aimed at overcoming the aforementioned shortcomings, is to provide a multichamber substrate processing apparatus in which substrates are always disposed correctly in a preset position inside a process chamber.

Another object of the subject invention is to provide a practical multichamber substrate processing apparatus that affords excellent productivity while occupying little space.

Aimed at overcoming the aforementioned shortcomings, the multichamber substrate processing apparatus of the subject invention aligns substrates inside a separate process chamber before they are transferred to the process chamber that requires the substrates to be aligned. The substrates are fed to the separate process chamber before being transferred to the process chamber in which the substrates are centered over a preset position and processed. This separate process chamber is provided with an alignment means. The alignment means performs center alignment whereby the position of the center of each substrate is calculated and the substrate is centered over a preset position. The alignment means performs, in addition to such center alignment, circumferential alignment whereby the circumferential position of the substrate is calculated and the circumferential position of the substrate is aligned with a preset position.

The process chamber equipped with the alignment means is a process chamber other than the process chamber requiring the longest time for processing a single substrate. The process chamber provided with the alignment means is a heating chamber, and the process chamber in which the substrate is centered over the preset position is a sputtering chamber or a CVD chamber. The heating chamber heats the substrate to the desired temperature before a thin film is deposited by sputtering or CVD. The heating chamber includes the alignment means and a substrate holder for heating the supported substrate with a built-in heater. The alignment means includes a stage for supporting the substrates, a rotating mechanism for rotating the stage, and a lifting mechanism for lifting the stage. The lifting mechanism lifts the substrate-carrying stage to the position corresponding to a detection line during center alignment and lowers the stage during substrate heating, whereupon the stage is inserted into the depression of the substrate holder, and the substrates are mounted on the upper surface of the substrate holder.

The multichamber substrate processing apparatus of the subject invention provides an autoload which can transfer a substrate between the lock-in cassette disposed inside the load lock chamber and the external cassette disposed on the atmosphere side. This autoload holds a plurality of cassettes together and simultaneously transfers them.

### BRIEF DESCRIPTION OF THE DRAWINGS

FIG. 1 is a schematic plan view depicting the multichamber substrate processing apparatus in accordance with a preferred embodiment of the present invention.

FIG. 2 is a schematic lateral view of the heating chamber 6.

FIG. 3 is a schematic plan view depicting the light-receiving surface 677 of the photodetector 672.

FIG. 4 is a schematic lateral view depicting the relation between the optical axis 670 and the center-positioned substrate Sb.

FIG. 5 depicts the results of calculating the peripheral distance D for a case in which the substrate Sb is a circular substrate Sb such as a semiconductor wafer having an orientation flat.

FIG. 6 depicts the curve obtained by the linear differentiation of the curve shown in FIG. 5.

FIG. 7 is a diagram illustrating the calculations performed to determine the center of an orientation flat from the data depicted in FIGS. 5 and 6.

FIG. 8 depicts the results of calculating the peripheral distance D for a case in which the substrate Sb is a circular substrate Sb such as a notched semiconductor wafer.

FIG. 9 depicts the curve obtained by the linear differentiation of the curve shown in FIG. 8.

FIG. 10 is a plan view illustrating the calculations performed to determine the center of the substrate Sb from data on peripheral distances.

FIG. 11 is a diagram illustrating the calculations necessary for circumferential alignment.

FIG. 12(a) is a diagram illustrating the calculations necessary for circumferential alignment.

FIG. 12(b) is a diagram illustrating the calculations necessary for circumferential alignment.

FIG. 13 is a schematic oblique view illustrating the operation of an autoloader preferred for use in the multichamber substrate processing apparatus of the subject embodiment.

FIG. 14 is a schematic plan view depicting a conventional multichamber-type substrate processing apparatus.

FIG. 15 is a schematic oblique view depicting the alignment device 5 shown in FIG. 14.

### DETAILED DESCRIPTION OF THE PREFERRED EMBODIMENTS

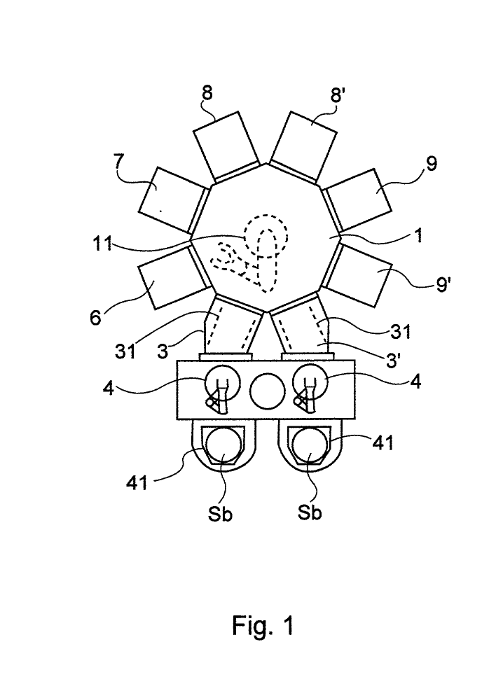

FIG. 1 is a plan view depicting the overall structure of a multichamber substrate processing apparatus in accordance with an embodiment of the subject invention. The multichamber substrate processing apparatus depicted in FIG. 1 includes a centrally located separation chamber 1, a plurality of process chambers 6, 7, 8, 8, 9, and 9 disposed around the separation chamber 1, and a pair of load lock chambers 3 and 3.

The apparatus of the subject embodiment is a thin-film deposition apparatus that combines sputtering and CVD. The two process chambers 8 and 8 are sputtering chambers, and the two process chamber 9 and 9 are CVD chambers. The process chamber 6 is a heating chamber for preheating a substrate Sb. The process chamber 7 is an etching chamber for etching off the native oxide film or protective film from the substrate surface prior to the manufacture of a thin film.

The substrate Sb is fed by the transfer robot 11 in the separation chamber 1 from one of the two load lock chambers 3 to the heating chamber 6, etching chamber 7, sputtering chamber 8, and CVD chamber 9 in a sequential manner. The substrate Sb is returned to the other load lock chamber 3 after the desired film deposition processing has been completed.

A feature of the apparatus of the subject embodiment is that before the substrate Sb is transferred to a process chamber for substrate processing, the central and circumferential positions of the substrate are set in a separate process chamber to which the substrate is temporarily transferred. The central or circumferential position must be set before the substrate is processed in the etching chamber 7, sputtering chamber 8, and CVD chamber 9. The central and circumferential positions are set in the heating chamber 6, to which the substrate Sb is transferred. The heating chamber 6 is provided with means (hereinafter “alignment means”) for setting the central and circumferential positions.

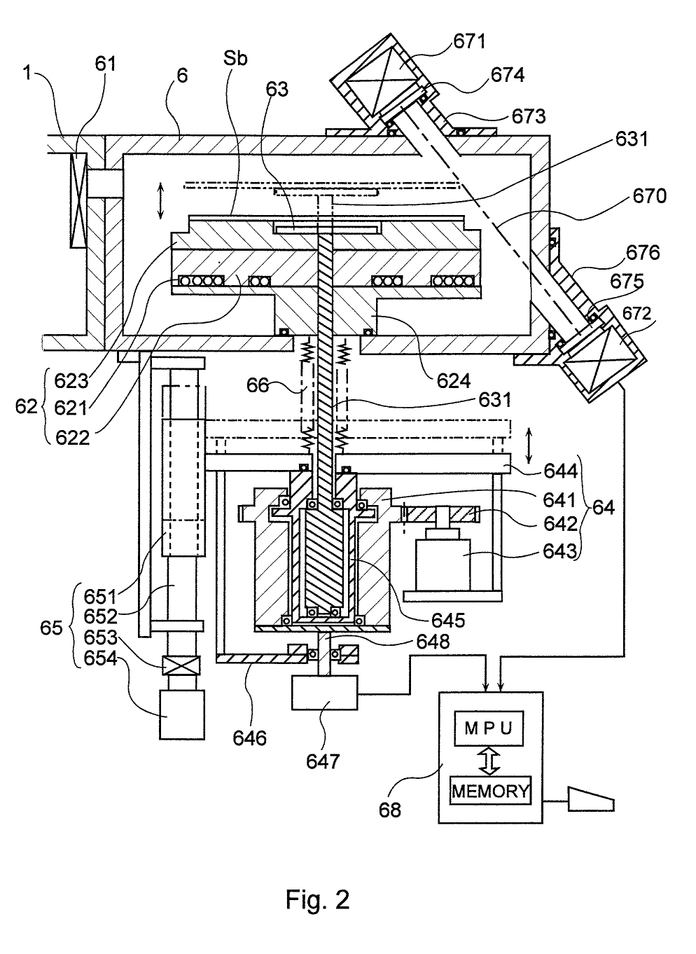

The structure of the heating chamber 6 will be described using FIG. 2. FIG. 2 is a schematic side view of the heating chamber 6. The heating chamber 6 is a sealed vacuum container shaped as a box. The heating chamber 6 is airtightly connected to the separation chamber 1 via a gate valve 61.

A substrate holder 62 for mounting and heating the substrate Sb is disposed inside the heating chamber 6. The substrate holder 62 comprises a heating block 622 with a built-in heater 621, and an upper block 623 provided above the heating block 622.

The heating block 622 is a stainless steel disk that is larger than the substrate Sb. The heating block 622 is fabricated by combining a stainless steel block and a block composed of another, highly thermal-conductive metal such as copper. The two blocks are diffusion-bonded in order to improve their thermal contact.

A resistance-heating component can be used as the heater 621 in the subject embodiment. The linear heater 621 is disposed as a coaxial circle or spiral around the central axis of the heating block 622. The heater 621 is connected to a heating power source (not shown), and is caused to generate heat when energized.

The upper block 623 is a member on the surface of which the substrate Sb is mounted during heating. It is a disk whose diameter is roughly equal to that of the substrate Sb. The upper block 623 is essentially composed of alumina. The upper block 623 is joined to the heating block 622 via a buffer (carbon sheet) to achieve good thermal contact.

The substrate holder 62 is fixed to the bottom of the heating chamber 6 with a holder-fixing component 624. The substrate holder 62 is cooled with water in order to quench the substrate holder 62 or to adjust its temperature.

A depression is formed in the surface of the upper block 623, as shown in FIG. 2. A stage 63 for mounting the substrate Sb is fitted into the depression. The stage 63 is a diskoid member whose diameter is less than that of the substrate Sb. The depression is shaped as a circle whose diameter is slightly greater than the diameter of the stage 63, and the stage 63 is fitted into this depression during the heating of the substrate Sb.

A post 631 is fixed to the stage 63. The post 631, whose tip is fixed to the center of the back surface of the stage 63, extends downward. A through hole extending in the vertical direction is formed in the centers of the upper block 623 and heating block 622. The cross-sectional area of the through hole is slightly greater than the cross-sectional area of the post 631, and the post 631 extends downward via this through hole.

The lower end of the post 631 is provided with a rotating mechanism 64 and a lifting mechanism 65. The rotating mechanism 64 comprises a driven gear 641, a drive gear 642, a rotational motor 643, and a holding plate 644. The driven gear 641 is installed such that it can rotate integrally with the post 631. The drive gear 642 meshes with the driven gear 641. The drive gear 642 is fixed to the output shaft of the rotational motor 643. The holding plate 644 supports the entire rotating mechanism 64.

The holding plate 644 is provided with a through hole for accommodating the post 631. A roughly discoid frame 645 extending downward around the outside of the through hole is fixed to the holding plate 644. The frame 645 has a bottomed shape. The frame 645 is provided with a roughly cylindrical, airtight inner space underneath the through hole. The lower end of the post 631 is disposed in the inner space of the frame 645. The frame 645 and post 631 are coaxial.

A projection shaped as a flange is provided to the outside surface of the frame 645. The driven gear 641 engages this projection via a bearing. The entire driven gear 641 has a roughly cylindrical shape, and gear teeth are provided to outwardly extending portions. The post 631 has a larger diameter at its lower end, as shown in FIG. 2. The lower surface of the post 631 engages the bottom surface of the frame 645 via a bearing.

The outer peripheral surface of the post 631 and the inner peripheral surface of the driven gear 641 face each other across a narrow gap, sandwiching the frame 645. The outer peripheral surface of the post 631 and the inner peripheral surface of the driven gear 641 are magnetically coupled. Magnets having different magnetic poles are provided to the outer peripheral surface of the post 631 and the inner peripheral surface of the driven gear 641. The portions of the outer peripheral surface of the post 631 and the inner peripheral surface of the driven gear 641 that face each other have reduced thickness. The internally located post 631 is rotated by magnetic coupling during the rotation of the externally located driven gear 641. The post 631 is rotated by the rotation of the driven gear 641 during the rotation of the rotational motor 643 and drive gear 642. The frame 645 is nonrotatably fixed to the holding plate 644.

When the post 631 rotates, the substrate Sb on the stage 63 is also rotated via the stage 63. The substrate Sb is rotated without slippage in tandem with the stage 63 by the frictional force between the back surface of the substrate Sb and the front surface of the stage 63. It is also possible to induce an electrostatic attraction in the front surface of the stage 63 and to hold the substrate Sb by electrostatic chucking.

An auxiliary bar 648 is provided such that it extends downwardly from the driven gear 641. The auxiliary bar 648, which is coaxial with the post 631, rotates in tandem with the driven gear 641 or post 631. The auxiliary bar 648 is held by auxiliary holding plate 646 by bearings. A rotary encoder 647 is provided at the lower end of the auxiliary bar 648. When the post 631 is rotated in such a manner, the auxiliary bar 648 rotates in tandem therewith, and its rotation angle is sensed by a rotary encoder 647.

The lifting mechanism 65 has a driven element 651. The driven element 651 supports the holding plate 644, which, in turn, supports the rotating mechanism 64. The driven element 651 is in threaded engagement with a ball screw 652. The ball screw 652 is linked to a lifting motor 654 via a joint 653. The ball screw 652 is rotated through the agency of the joint 653 during the rotation of the lifting motor 654. The driven element 651 can thus be moved up and down in a straight line. As a result, the stage 63, post 631, and rotating mechanism 64 supported by the holding plate 644 can be raised or lowered in their entirety.

A bellows 66 is provided between the holding plate 644 and the heating chamber 6. The bellows 66 prevents leakage through the opening formed in the bottom plate of the heating chamber 6, through which the post 63 passes.

When the post 631 is lifted by the lifting mechanism 65, the stage 63 supported on the post 631 is also lifted, as is the substrate Sb mounted on the stage 63. In the apparatus of the subject embodiment, a photoemitter 671 and a photodetector 672 are provided such that the edge of the substrate Sb in the lifted position lies in the optical path of the photoemitter 671 and the photodetector 672.

In the subject embodiment, a semiconductor laser is used for the photoemitter 671, and the oscillation frequency is 780 nm. The photoemitter 671 is fixed to the heating chamber 6 by a frame 673. An emission window 674 is provided to the front surface of the photoemitter 671. The frame 673 or emission window 674 are airtightly attached to the heating chamber 6 so as to prevent vacuum leakage from the heating chamber 6. An adequately sized opening for passing the light from the photoemitter 671 is provided in the wall of the heating chamber 6 on the emission side.

The photodetector 672 should have sufficient detection sensitivity for the light emitted by the photoemitter 671. A photodiode array is used in the subject embodiment. The front surface of the photodetector 672 is provided with an admittance window 675; the admittance window 675 of photodetector 672 is airtightly connected to the heating chamber 6 by a frame 676. An adequately sized opening for passing the light incident on photodetector 672 is also provided to the wall of the heating chamber 6 on the admission side.

Light emitted by the photoemitter 671 enters the heating chamber 6 through the emission window 674. While some of the light is blocked by the end of the substrate Sb in the lifted position, the remaining light enters the photodetector 672 through the admittance window 675. A signal representing the intensity of the light received by the photodetector 672 is amplified by an amplifier inside the photodetector 672, and the result is sent to a computer 68. The computer 68 is also presented with a signal from the rotary encoder 647.

In the subject embodiment, the stage 63, post 631, rotating mechanism 64, lifting mechanism 65, photoemitter 671, and photodetector 672 provided to the aforementioned heating chamber 6 constitute an alignment means, as do the computer 68 and the arm of the transfer robot 11. The alignment means will now be described with reference to a central and circumferential alignment system operated using these elements.

For alignment, a substrate Sb is placed on the stage 63 by the transfer robot 11 inside the separation chamber 1, and the substrate Sb is then moved to a position corresponding to a prescribed height (hereinafter “alignment level”) by the lifting mechanism 65. The substrate Sb is subsequently rotated by the rotating mechanism 64 while the photoemitter 671 is actuated. An output signal obtained by converting the light incident on the photodetector 672 into an electric signal (hereinafter abbreviated as “an output signal”) is processed by the computer 68. As a result of such processing, the position in which the arm of the transfer robot 11 is to accept the substrate Sb is determined. Alignment is completed by the actual acceptance of the substrate Sb and its removal from the stage 63 by the transfer robot 11 in the designated position.

The description that follows primarily deals with the processing program stored in the computer 68.

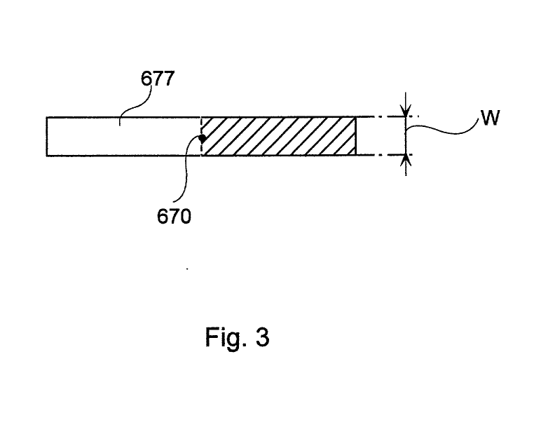

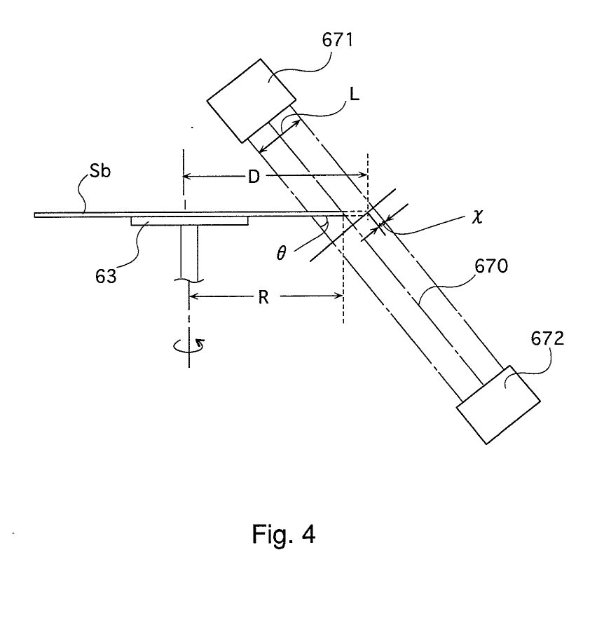

The manner in which the distance between the center of rotation and the points along the edge of the substrate Sb (hereinafter “peripheral points”) is calculated will now be described using FIGS. 3 and 4. FIG. 3 is a schematic plan view depicting the light-receiving surface 677 of the photodetector 672. FIG. 4 is a schematic side view depicting the positional relation between an optical axis 670 and a substrate Sb whose central position has been set.

In the subject embodiment, a photodiode array is used as the photodetector 672. The light-receiving surface 677 of the photodetector 672 has a narrow rectangular shape, as shown in FIG. 3. The photodetector 672 is oriented such that the light-receiving surface 677 thereof is perpendicular to the optical axis 670, and the light-receiving surface 677 is centered over the optical axis 670.

The photoemitter 671 houses a beam expander and collimator lens optical system. Light emitted by the photoemitter 671 forms a parallel beam whose width is designated by L in FIG. 4. In terms of cross-sectional area, the light-receiving surface 677 shown in FIG. 3 is slightly larger than the rays of this parallel beam, and the surface is oriented perpendicular to the optical axis 670 to allow all the rays to strike the target perpendicularly. As shown in FIG. 3, the components are arranged such that the optical axis 670 passes through the center of the light-receiving surface 677.

In this case, the magnitude of the output signal generated when the beams are blocked by the substrate Sb and cast on the photodetector 672 depends on the position of the substrate Sb in relation to the optical axis 670.

In the subject embodiment, the edge of the substrate Sb is aligned with the optical axis 670 that connects the photoemitter 671 and the photodetector 672 when, as shown in FIG. 4, the substrate Sb is at the same height as the alignment level, and the center of the substrate Sb coincides with the center of rotation (when the center position has been set).

Assuming that S0 is the magnitude of the signal outputted when the center position has been set, half of the rays emitted by the photoemitter 671 are blocked by the substrate Sb, and the remaining half are directed to the photodetector 672. As shown by the hatching in FIG. 3, light strikes only half the light-receiving surface. The output signal S0 of the photodetector will therefore be S0=Smax/2, where Smax is the magnitude of the signal outputted when all the rays emitted by the photoemitter 671 reach the photodetector 672. The width w of the light-receiving surface 677 shown in FIG. 3 is sufficiently less than the curvature of the substrate Sb, and the outline of the rays blocked by the substrate Sb is regarded as linear.

As shown by the dotted line in FIG. 4, the number of rays emitted by the photoemitter 671 and blocked by the substrate Sb increases when the center of the substrate Sb does not coincide with the center of rotation and the substrate Sb is shifted outward from the center of rotation. As a result, the number of rays reaching the photodetector 672 decreases, and the output signal is reduced. The equation

S0−Sd=α(D−R) (1)

(α=(Smax sinθ)/L))

can be obtained from

Sd=kx=k(L/2−(D−R)sin θ), S0=kL/2, Smax=kL (k is a coefficient of proportionality),

where D is the distance between the actual center of rotation and the edge of the substrate Sb (hereinafter “peripheral distance”), Sd is the magnitude of the output signal, and θ is the angle between the rays and the substrate Sb. It should be noted that R is the distance from the center of rotation of the surface perpendicular to the rotational axis to the optical axis 670. R is equal to the radius of the substrate Sb when the center of the substrate Sb coincides with the center of rotation. Based on Equation (1) above, the peripheral distance D can be calculated as

D=R+(S0−Sd)/α (2)

S0 is the magnitude of the output signal obtained when the substrate Sb is preset using a laser-based distance meter in such a way that the center of the substrate Sb coincides with the center of rotation. The S0 value thus determined is entered into the computer 68 in advance and is used for the computation of the peripheral distance D.

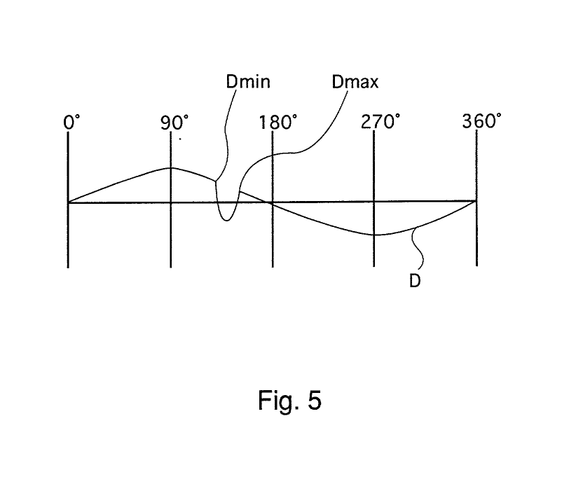

FIG. 5 shows the results of calculating the peripheral distance for a case in which the substrate Sb is a circular substrate Sb such as a semiconductor wafer provided with an orientation flat. In FIG. 5, the abscissa shows the angle of rotation and the ordinate shows the peripheral distance D.

When the center of the substrate Sb and the center of rotation do not coincide and the substrate Sb rotates off-center, the distance between the center of rotation and the edge of the substrate Sb, rather than being constant, varies in relation to the optical axis 670, as described above. These variations are periodic, and the variations in the peripheral distance after the stage 63 has rotated 360 degrees describe a roughly sinusoidal wave, as shown in FIG. 5. The curve described by D has the shape shown in FIG. 5 when calculated in accordance with the aforementioned program by sampling Sd at a prescribed sampling period during the rotation of the stage 63.

Following is a description of a program for calculating the position of the center of the substrate Sb and the position of the reference points along the edge of the substrate Sb on the basis of data on the peripheral distance D. The center of the substrate Sb can be calculated using three types of data on the peripheral distance D thus sampled. It is, however, impossible to perform accurate calculations if these three types of data contain data on noncircular portions such as orientation flats. For noncircular portions such as orientation flats, it is necessary to determine positions that could serve as reference points for alignment in the circumferential direction. In view of this, calculations aimed at determining the position of such noncircular portions are first performed.

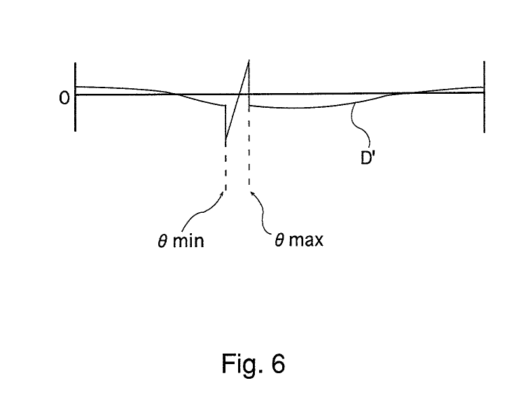

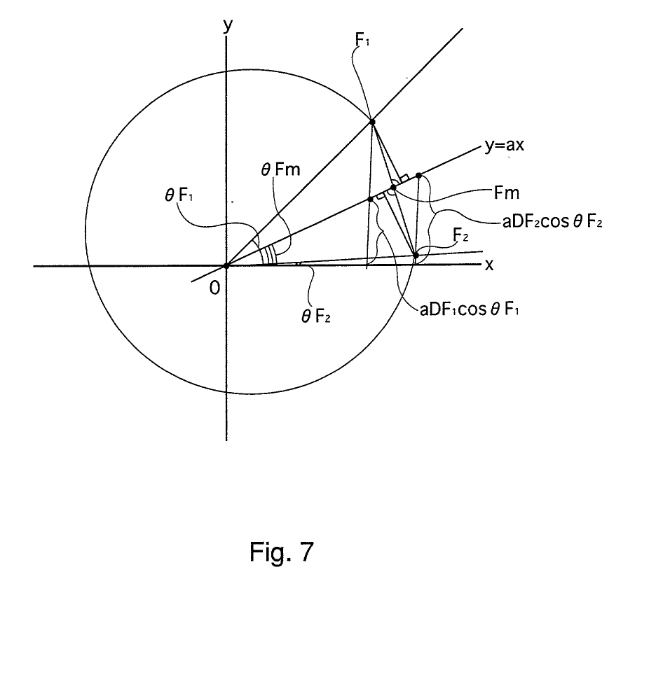

The curve for the peripheral distance D shown in FIG. 5 is calculated as a linear differential when a noncircular portion (orientation flat) is calculated. As a result, the curve shown in FIG. 6 is obtained. FIG. 6 depicts a curve obtained by the linear differentiation of the curve shown in FIG. 5. FIG. 7 illustrates the procedures involved in calculating the center of the orientation flat on the basis of the data shown in FIGS. 5 and 6.

As shown in FIG. 6, periodic variations produce a very small flat (such data will be referred to as D′ hereinbelow). The output signal undergoes an abrupt change in the area of the orientation flat. Rotation angles min and max, which are obtained for the minimum value D′min and maximum value D′max of data D′, correspond to the rotation angles at which the start and end points of the orientation flat lie on the optical axis.

The center of the orientation flat is commonly adopted as the reference point for alignment in the circumferential direction. It should be noted that the angle that is exactly between the rotation angles min and max does not necessarily correspond to the position of the central point of the orientation flat. The position of the central point of the orientation flat is determined by performing the following calculations.

In FIG. 7, the origin of a rectangular coordinate system is placed in the center of rotation O. F1, F2, and Fm are taken to be, respectively, the start point, end point, and center point of an orientation flat. In addition, DF1 is taken to be the distance from the origin to F1, DF2 the distance from the origin to F2, θF1 the angle that the line segment connecting the origin and F1 makes with the x-axis, and θF2 the angle that the line segment connecting the origin and F2 makes with the x-axis. Inclination a can be calculated in accordance with equation (3) below, where a is the inclination of the straight line connecting the origin and Fm.

|a DF1 cos θF1−DF1 sin F1|=|a DF2 cos θF2−DF2 sin θF2|,

whence

(DF1² cos² θF1−DF2² cos² θF2)a²−2(DF1² cos θF1 sin θF1−DF2² cos θF2 sin θF2)a+DF1² sin² θF1−DF2² sin² θF2=0 (3)

In Equation (3) above, DF1, DF2, θF1, and θF2 are constants that constitute the aforementioned data on peripheral distances. It is therefore possible to substitute these data into Equation (3) and to calculate a by solving quadratic equation (3). The angle Fm through which the stage 63 rotates when the center point Fm of the orientation flat lies in the optical path (this angle will hereinafter be referred to as “the orientation flat center point detection angle”) can be represented as Fm=tan⁻¹ a.

Following is a description of a method for calculating the position when the noncircular portion along the edge of the substrate Sb is a small cutout (hereinafter referred to as “a notch”).

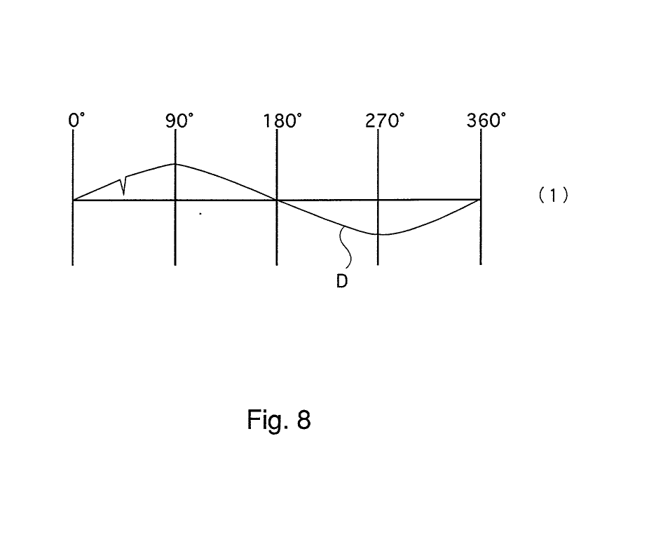

FIG. 8 depicts the results of calculating the peripheral distance for a case in which the substrate Sb is a circular substrate such as a notched semiconductor wafer. In FIG. 8, the rotation angle of the stage 63 is plotted on the horizontal axis, and the peripheral distance D on the vertical axis.

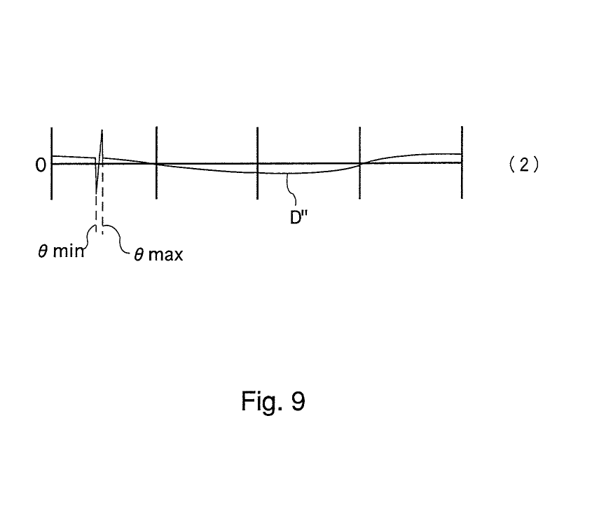

The curve shown in FIG. 9 can be obtained by the linear differentiation of the curve for the peripheral distance D shown in FIG. 8. FIG. 9 depicts a curve obtained by the linear differentiation of the curve shown in FIG. 8.

As shown in FIG. 9, linearly differentiating the curve shown in FIG. 8 markedly reduces and flattens periodic changes (this kind of data will be referred to hereinbelow as D″). A wave in the form of an abrupt ripple corresponds to the notched portion. The width of the notch is much less than the circumference of the substrate Sb, and the notch is commonly shaped as a triangle, semicircle, half-ellipsoid, or the like. Calculations are performed in the manner described below in order to calculate the rotation angle reached by the stage 63 when the notch lies in the optical path (this angle will hereinafter be referred to as “the notch detection angle θn”).

Rotation angles θmin and θmax are calculated when the minimum and maximum values of data D″ are obtained. In FIG. 8, the notch detection angle θn is defined as the rotation angle achieved when the peripheral distance reaches its minimum value in the interval between the rotation angles θmin and θmax.

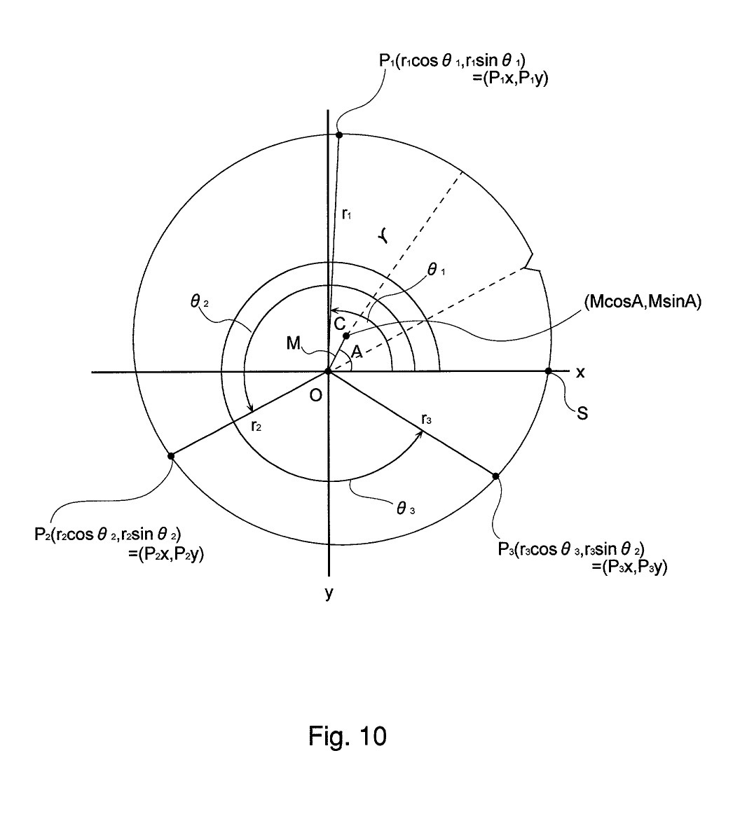

Following is a description of calculations aimed at finding the center of the substrate Sb on the basis of data on peripheral distances. FIG. 10 is a plan view illustrating the manner in which the center of the substrate Sb is calculated based on the data concerning peripheral distances.

The center of the substrate Sb can be calculated using three types of data derived from the data on peripheral distances. It is, however, impossible to perform accurate calculations if these three types of data contain information about the notch, which is a noncircular portion, so such notch-related data are excluded therefrom.

Data corresponding to three rotation angles (60, 180, and 240 degrees from the notch detection angle θn) are adopted as data on peripheral distances. The three peripheral points of the substrate Sb that correspond to these data are designated P1, P2, and P3. The positional relation between the notch and the three points (P1, P2, and P3) is shown in FIG. 10.

In FIG. 10, C is the center of the substrate Sb, M is the distance from the center of rotation O to C, and A is the angle that the line segment connecting O and C makes with the x-axis. In FIG. 10, the point S where the peripheral edge of the substrate Sb intersects the x-axis on the positive side corresponds to a rotation angle of zero degrees (or 360 degrees) in the data on peripheral distances shown in FIGS. 8 and 9. Angle A is an angle indicating the degree of alignment of the straight line passing through the center of the substrate Sb with the optical axis 670 during the rotation of the stage 63.

The center of the substrate Sb can be defined by calculating the aforementioned angle A and distance M. In FIG. 10, r1, r2, and r3 are the distances between the center of rotation O and P1, P2, and P3, respectively; and θ1, θ2, and θ3 are the respective angles that the line segments connecting O with P1, P2, and P3 make with the line segment OS (on the positive side of the x-axis). Assuming that the coordinates of the three points are

P1(r1 cos θ1, r1 sin θ1)=(P1x, P1y)

P2(r2 cos θ2, r2 sin θ2)=(P2x, P2y)

P3(r3 cos θ3, r3 sin θ3)=(P3x, P3y)

we can conclude that

(P1x−M cos A)²+(P1y−M sin A)²=r²

(P2x−M cos A)²+(P2y−M sin A)²=r²

(P3x−M cos A)²+(P3y−M sin A)²=r²

(where r designates the substrate radius).

Based on this, A can be calculated using Equation (4), and M can be calculated using Equation (5).

tan A={k2(P1x−P2x)−k1(P2x−P3x)}/{k1(P2y−P3y)−k2(P1y−P2y)} (4)

M=(½)×[(k1/{P1x−P2x)cos A+P1y−P2y)sin A} (5)

In the Equations (4) and (5) above, k1=r1²−r2² and k2=r2²−r3².

The position of the center of the substrate Sb in relation to the center of rotation can thus be calculated. The setting of the center position is completed by controlling the transfer robot 11 and allowing its arm to receive the substrate Sb in such a way that a specific point on the arm of the transfer robot 11 coincides with the resulting central position of the substrate Sb. The position of the substrate Sb in the circumferential direction has not yet been established, however, so this position is then set in the following manner.

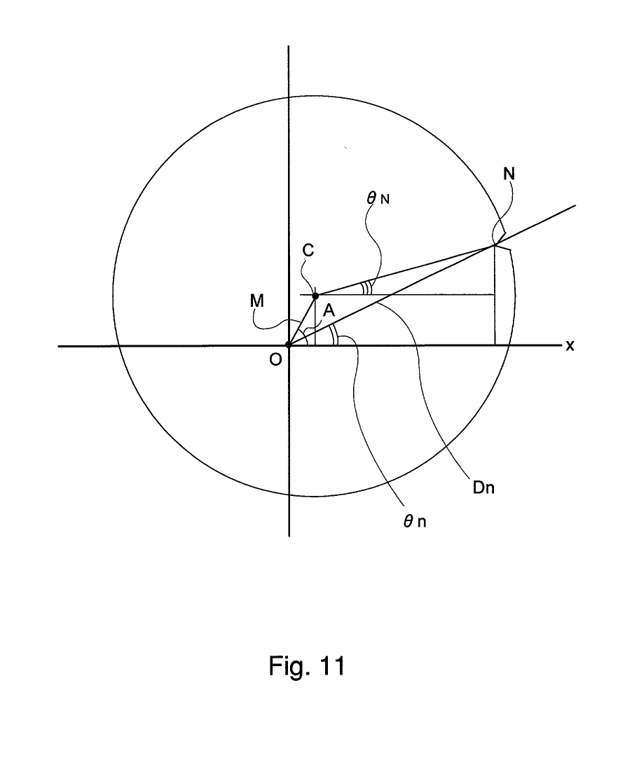

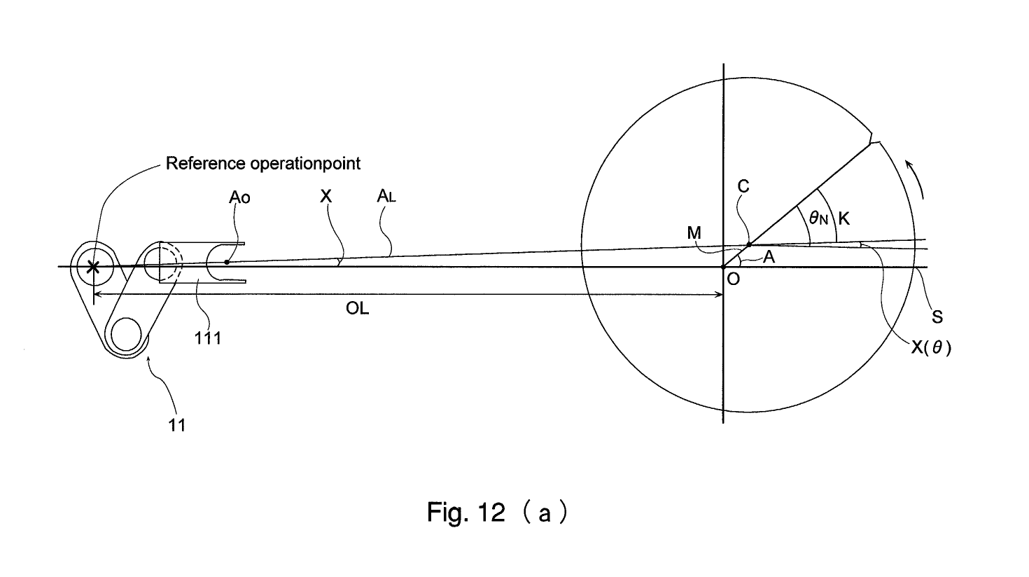

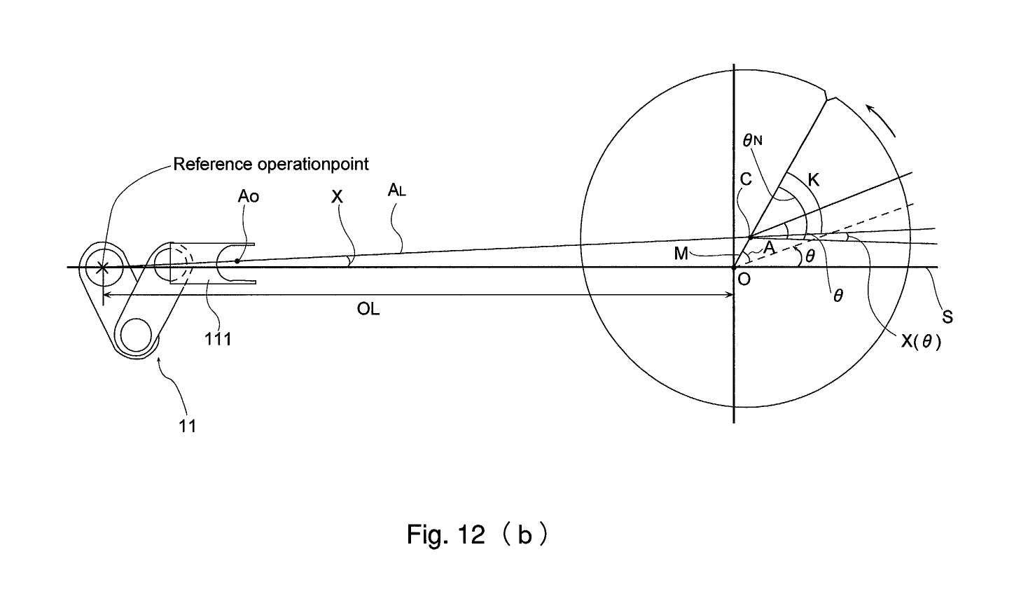

Setting the circumferential position involves selecting the desirable magnitude for the angle that the line segment connecting the center of the substrate Sb and the reference point along the peripheral edge of the substrate Sb makes with the direction of the fork 111 (see FIG. 12) of the transfer robot 11 (this angle will hereinafter be referred to as “the alignment angle”). This procedure will now be described in detail using FIGS. 11, 12a, and 12b. FIGS. 11 and 12 are diagrams illustrating the calculations required for setting the circumferential position.

Assuming that N is the angle that the line segment connecting the center C of the substrate Sb and point N of the notch makes with the x-axis in FIG. 11, we obtain

tan θN=(Dn sin n−M sin A)/(Dn cos θn−M cos A) (6)

In Equation (6), Dn is a quantity known from the data concerning the peripheral distance at the notch detection angle n, and M is a quantity that has already been calculated. Thus, substituting these values into Equation (6) makes it possible to calculate angle N as tan⁻¹. Although FIG. 12 depicts an example involving a notch, the same reasoning can be applied to an orientation flat.

The transfer robot 11 used in the subject embodiment is configured such that the substrate Sb is mounted on and held by the fork 111 at the distal end thereof. The fork 111 is shaped as a rectangular plate having a U-shaped notch. The direction (hereinafter referred to as “the fork reference direction”) of the fork 111 of the transfer robot 11 is set to coincide with the depth direction of the U-shape that passes through the center point (fork center) A0 of the U-shaped notch.

The movement performed by the fork 111 of the transfer robot 11 in order to accept the substrate Sb is set based on the reference point for the operation of the transfer robot 11. In the subject embodiment, the reference point for the operation of the transfer robot 11, which is an articulated robot, is located on the axis of rotation that is set at the closest point of the articulated arm (designated as “×” in FIGS. 12a and 12b).

The reference operation point is positioned on the center axis of the separation chamber 1 shown in FIG. 1. The settings are selected such that the fork 111 accepts the substrate Sb by moving in a straight line along a line (hereinafter referred to as “the fork advance line”) AL connecting the calculated center C of the substrate Sb and the reference point × thereof.

The fork 111 is moved by establishing the travel distance and travel direction for the fork 111 on the basis of the reference point × for the operation of the robot. When the procedure for receiving the substrate Sb is started, the fork 111 is moved such that the fork center A0 is brought into a position (hereinafter referred to as “the fork operation origin”) that is slightly closer to the substrate Sb than the reference operation point × on the fork advance line AL. The rotational orientation of the fork 111 is also set such that the reference direction of the fork is aligned with the fork advance line AL. The fork 111 is moved in a straight line while the reference direction of the fork is aligned with the fork advance line AL, and the fork center A0 is made to coincide with the center of the substrate Sb.

The direction and distance needed to move the fork 111 in a straight line are calculated in the following manner. First, the angle K shown in FIG. 12 is an angle that the line segment connecting the notch N and the center C of the substrate Sb makes with the reference direction of the fork. Angle K is the aforementioned alignment angle. Alignment is a procedure involving setting the alignment angle K shown in FIGS. 12a and 12b to the desired value. This procedure is performed by rotating the substrate Sb. The angle K varies when the substrate Sb is rotated around its center of rotation.

Here, as shown in FIG. 12b, the relation expressed by Equation (7) below can be written for the following parameters: the angle X(θ) that the line segment connecting the reference operation point × and the center of rotation O makes with the fork advance line AL, the alignment angle K, the angle N calculated as described above, and the rotation angle of the stage 63.

θN+θ=K+X(θ) (7)

A noteworthy feature of Equation (7) is that X(θ) is a function of, as demonstrated by Equation (8).

X(θ)=tan⁻¹ M sin(A+θ)/(OL+M cos(A+θ)) (8)

Consequently, it is not only K but also X that vary when the substrate Sb is rotated.

With this in mind, the following can be obtained by modifying Equation (7):

θ=K+X(θ)−θN (9)

In Equation (9), the magnitude of K is preset as the alignment angle. In addition, θN is a quantity that has already been calculated, as indicated above. In Equation (9), therefore, these values are constants. It is, however, difficult to obtain the value of θ by directly solving Equation (9). θ is calculated by the computer 68 performing iterative computations. The right side of Equation (8) is calculated by the subsequent substitutions of θ values between −180 and 180 C (for example, in 1° increments). An attempt is then made to calculate the θ value for a case in which the value on the right side approximates most closely the substituted θ value.

Calculating the rotation angle in such a manner makes it possible to rotate the stage 63 through this angle. As a result, the line connecting the notch position N and the center C of the substrate Sb makes a constant angle with the fork advance line AL.

The distance between the reference operation point × and the substrate center C is calculated based on the angle X and the distance O between the center of rotation O of the stage 63 and the reference operation point × of the transfer robot 11. The distance traveled by the fork center A0 in a straight line can be calculated when this distance is reduced by the distance from the reference operation point × of the transfer robot 11 to the fork operation origin (this distance will be preset and fixed hereinbelow). Moving the fork center A0 over this distance in the direction of angle X causes the fork center A0 and the center C of the substrate Sb to coincide, and the substrate Sb to be mounted on the fork 111. In more exact terms, the fork center A0 is positioned on the vertical line passing through the center C of the substrate Sb, the fork 111 is lifted, and the substrate Sb is mounted on the fork 111. The central and circumferential positions are thus set, and the substrate Sb is mounted on the fork 111.

To summarize, the program is executed by calculating the following parameters in sequence: peripheral distance, orientation flat center or notch position, center C of substrate Sb, and rotation angle θ for circumferential alignment.

The other process chambers constituting the apparatus of subject embodiment will now be described with reference to FIG. 1. The etching chamber 7 comprises a gas introduction means, a plasma formation means, and a high-frequency power source. The gas introduction means (not shown) introduces an inert gas such as argon or nitrogen into the etching chamber 7. The plasma formation means (not shown) forms a plasma by applying high-frequency energy to the introduced gas. The high-frequency power source (not shown) applies a negative self-bias voltage to the substrate Sb by applying a high-frequency voltage to the substrate Sb, causing interaction between the plasma and the high frequency.

The positive ions in the plasma are drawn out by the negative self-bias voltage, directed toward the substrate Sb, and used to shave the native oxide film or protective film from the surface of the substrate Sb. As a result, the clean surface of the original material constituting the surface of the substrate Sb is exposed.

The sputtering chambers 8 and 8 are designed to deposit the desired thin film on the surface of the substrate Sb by magnetron sputtering. A target (not shown) is provided such that the front surface to be sputtered is exposed into one of the sputtering chambers 8, 8. A negative direct-current voltage or high-frequency voltage is applied to this target. A magnet structure (not shown) is provided behind the target, and arching magnetic lines of force going through the target are formed in circles. Also provided is a gas introduction means (not shown) for introducing an inert gas such as argon or nitrogen into the sputtering chamber 8, 8.

The gas thus introduced is caused to create a discharge by the voltage applied to the target, yielding a plasma. The positive ions in the plasma sputter the target, and the target material thus sputtered reaches the substrate Sb. As a result, a thin film of target material is deposited on the surface of the substrate Sb. Occasionally, the target material thus sputtered reacts with the gas, and a thin film consisting of the reaction product is deposited on the surface of the substrate Sb.

The CVD chambers 9 and 9 include a gas introduction means (not shown) for introducing a reactive gas inside, and an energy application means (not shown) for initiating a gas-phase reaction by applying energy to the gas thus introduced. The energy application means is designed to form a plasma by applying high-frequency energy to the gas in the case of plasma-enhanced CVD, and to heat the substrate Sb to a constant temperature, causing reactions to be initiated by the heat generated by the surface of the substrate Sb in the case of thermal CVD.

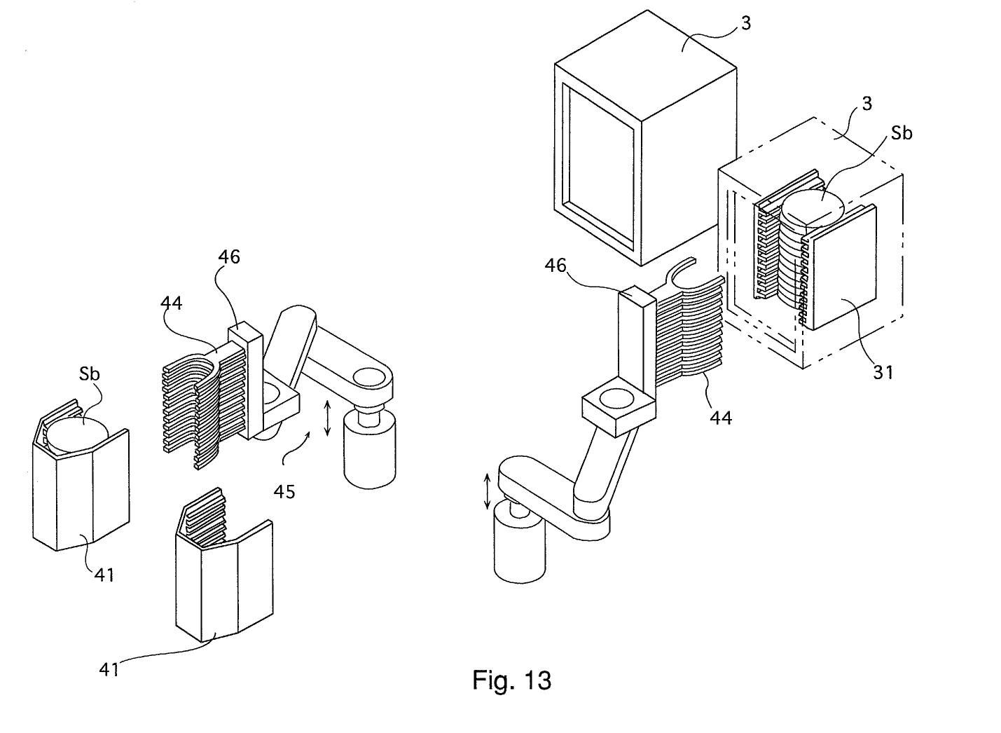

Following is a description of the structure of an autoloader 4 preferable for use with the multichamber substrate processing apparatus of the subject embodiment. FIG. 13 is a schematic oblique view depicting the operation of the autoloader preferable for use with the multichamber substrate processing apparatus of the subject embodiment.

A major distinctive feature of the autoloader 4 depicted in FIG. 13 is that a plurality of substrates Sb can be transferred in one batch from an external cassette 41 to an in-lock cassette 31. The autoloader 4 principally comprises a plurality of holding fingers 44 and a transport mechanism 45 for integrally moving this plurality of holding fingers 44. Each holding finger 44 is a roughly U-shaped member.

The plurality of holding fingers 44 are disposed such that they are superposed in the vertical direction at regular intervals. Each holding finger 44 is optionally provided with an electrostatic chucking mechanism for holding a substrate Sb. Such holding fingers 44 are held together by a finger holder 46. The finger holder 46 is linked to the transport mechanism 45.

An articulated robot is commonly used for the transport mechanism 45. The articulated robot is capable of moving the finger holder 46 to an arbitrary position within the operating range of the robot.

The external cassette 41 and in-lock cassette 31 have the same positional relations for the substrates Sb being stored. In both the cassettes 31 and 41, the substrates Sb are held horizontally such that they are superposed with each other in the vertical direction at regular intervals. The distance separating the substrates Sb is the same for both the cassettes 31 and 41.

To operate the autoloader 4, the finger holder 46 is first moved by the transport mechanism 45, and the holding fingers 42 are inserted into the guides supporting the substrates Sb in the external cassette 41. The finger holder 46 is lifted, mounting the substrates Sb on the holding fingers 44. The finger holder 46 is moved in this state, and a plurality of substrates Sb are transferred in one batch to the in-lock cassette 31. In the in-lock cassette 31, the finger holder 46 is lowered slightly to ease the substrates Sb onto the protrusions at each tier of the in-lock cassette 31. The holding fingers 42 are then retracted from the in-lock cassette 31, returning to the standby position.

The use of the autoloader 4 dramatically increases transportation efficiency, and thus holds promise in terms of delivering much higher productivity. By contrast, it is difficult to individually set central and circumferential positions with the aid of an alignment device 5 when substrates are transferred from an external cassette 41 to an in-lock cassette 31, as was the case in the past. The drawbacks of using an autoloader 4 can thus be overcome by equipping a multichamber substrate processing apparatus with the alignment means of the subject embodiment.

The operation of the entire multichamber substrate processing apparatus of the subject embodiment will now be described in brief.

A plurality of substrates Sb are transferred in one batch to an in-lock cassette 31 by the aforementioned autoloader 4. The transfer robot 11 in the separation chamber 1 retrieves individual substrates Sb from the in-lock cassette 31 and feeds them to the heating chamber 6.

In the heating chamber 6, the stage 63 that has accepted the substrate Sb is lowered to ease the substrate Sb on the upper block 623 of the substrate holder 62. The heater 621 inside the heating block 622 is switched on in advance, and the substrate Sb thus mounted is heated by the heat generated by the heater 621. The temperature of the substrate Sb is monitored by a thermocouple or a radiation thermometer (not shown), the heater 621 is controlled, and a constant heating temperature is maintained for a given time.

When the given time has elapsed, the lifting mechanism 65 is actuated, the stage 63 is lifted, and the substrate Sb is moved to the height corresponding to the alignment level. The position of the center C of the substrate Sb is calculated by an alignment means as described above, and the magnitude of the rotation angle θ for circumferential alignment is calculated. The stage 63 is rotated through the rotation angle θ for circumferential alignment. The transfer robot 11 inside the separation chamber 1 then moves such that the fork center A0 coincides with the center of the substrate Sb, and the substrate Sb is retrieved, as described above. Center alignment and circumferential alignment are thus completed.

The transfer robot 11 then transfers the substrate Sb in this state to the etching chamber 7. The native oxide film or protective film on the surface is removed by etching as described above, and the substrate Sb is transferred to the sputtering chamber 8 by the transfer robot 11. A film is deposited by sputtering in the sputtering chamber 8 as described above, the substrate Sb is transferred to the CVD chamber 9, and a film is deposited by CVD. The substrate Sb is then returned to the original load lock chamber 3 or to the other load lock chamber 3. On occasion, the substrate is introduced into a cooling chamber and cooled while being transferred from the CVD chamber 9 to the load lock chamber 3.

Individual substrates Sb are thus retrieved from one of the load lock chambers 3, sequentially processed, and ultimately returned to the load lock chamber 3. If a given number of substrates Sb are stored in the in-lock cassette 31 of the load lock chamber 3, the autoloader 4 is actuated, and this given number of substrates Sb are transferred in one batch to the external cassette 41.

Continuous deposition of a contact film/barrier film will now be described as an example of a substrate processing performed using the above-described procedure. A contact film/barrier film is designed, for example, to be interposed between interconnecting wires and a channel surface (underlayer) in an electrode component of a FET (field-effect transistor). Such a contact film/barrier film is designed to prevent mutual diffusion between the channel surface and the interconnecting wires while ensuring electrical conductivity between them. Titanium films are commonly used as contact films, which are interposed primarily to improve electrical conductivity. Titanium nitride is commonly used for barrier films, which are interposed primarily to prevent mutual diffusion. Multilayer film structures obtained by laminating titanium nitride films to titanium films are required.

To form such a structure, argon gas is introduced into the sputtering chamber 8, a titanium target is sputtered, and a titanium film is allowed to deposit on the surface of a substrate Sb. This substrate Sb is transferred in a vacuum to the CVD chamber 9 via the separation chamber 1. A gas obtained by mixing nitrogen gas and a gaseous titanium compound such as titanium chloride is introduced into the CVD chamber 9 to perform plasma-enhanced CVD. The gaseous titanium compound is decomposed in the plasma, titanium and nitrogen are allowed to react, and a titanium nitride film is deposited on the surface of the substrate Sb.

In the multichamber substrate processing apparatus of the subject embodiment, the etching chamber 7 is provided with an alignment means. This means is important for setting the position of the center or circumference of the substrate immediately before it is transferred to a process chamber (hereinafter referred to as “an alignment-requiring chamber”), where processing can only be performed after the central or circumferential position of the substrate has been set. Because the route traveled, or the procedures performed, between the alignment of the substrate Sb and its transfer to the alignment-requiring chamber are minimized, the likelihood that the set position will be changed by an external factor is less than that afforded by the prior art.

Another reason that an alignment means is disposed inside the heating chamber 6 and that central or circumferential alignment is performed therein is that such alignment is carried out in one of any process chambers other than the process chamber which can process the least number of substrates Sb in all process chambers, and high productivity is thereby maintained. The time needed for processing a single substrate Sb in each process chamber varies with processing capacity. The introduction and removal of substrates Sb into and from process chambers are limited by the processing time of the slowest processing chamber. In other words, even when the processing of a substrate Sb in a process chamber has been completed, this substrate must remain in this chamber and cannot be transferred to the next processing chamber until the processing has been completed in the slowest process chamber (hereinafter referred to as “the limiting chamber”).

In the subject embodiment, a process chamber other than the limiting chamber is provided with an alignment means, making it possible to perform alignment during idling (that is, until the substrate is transferred to the next process chamber). There is, therefore, no increase in time or reduction in productivity.

Although alignment was performed after the substrate Sb had been heated, it is also possible to perform alignment prior to heating. When the substrate Sb is introduced into the heating chamber 6 by the transfer robot 11 and mounted on the stage 63, the stage 63 is moved to the alignment level and rotated. The following parameters are calculated: the position of the center C of the substrate Sb, the position of the notch or of the center of the orientation flat of the substrate Sb, and the magnitude of the rotation angle θ for circumferential alignment. The stage 63 is lowered, and the substrate Sb is mounted on the substrate holder 62 and heated there for a prescribed time. The stage 63 is lifted and rotated through the rotation angle θ for circumferential alignment, after which the substrate Sb is received by the arm of the transfer robot 11 while the reference point of the arm is made to coincide with the center of the substrate Sb.

It is even better in the above-described case for the position of the substrate Sb to be changed by the transfer robot 11 before the substrate Sb is heated, and for the substrate to be heated after it has been positioned. After the position of the center C of the substrate Sb and the rotation angle θ for circumferential alignment have been calculated, the stage 63 is rotated through the rotation angle for circumferential alignment, and the substrate Sb is temporarily received by the arm in a state in which the reference point of the arm is made to coincide with the center of the substrate Sb.

The substrate Sb is again mounted on the stage 63 while the reference point of the arm is made to coincide with the center of rotation. The stage 63 is lowered, and the substrate Sb is mounted on the substrate holder 62 and heated. When this is done, the center axis of the substrate holder 62 and the center of the substrate Sb coincide, and the substrate Sb is heated in a state in which its position in the circumferential direction coincides with the set position. Heating reproducibility is therefore improved.

The space inside the above-described heating chamber 6 is used efficiently when an alignment means is disposed inside this heating chamber. The multichamber substrate processing apparatus of the subject embodiment requires less space than the structure in which an alignment device 5 is provided between the external cassette 41 and load lock chamber 3, as in the prior art.

In particular, there is no need for the heating chamber 6 to be provided with a wide internal space when alignment is accomplished by mounting the substrate Sb and rotating it on a stage 63 that is provided separately from, but coaxially with, the substrate holder 62. In this case, the heating chamber 6 can be made less bulky. This option is preferred because the rotational mechanism is simpler than when a substrate holder 62 containing a built-in heater 621 is rotated.

As described above, substrates are positioned in a separate process chamber in accordance with the present invention before being transferred to the process chamber that requires alignment. The substrates are always processed in the correct central position, process reproducibility is improved, and less space is needed.

Another merit of the present invention is that process reproducibility is further improved because the substrates are always processed in the correct circumferential position. Yet another merit of the present invention is that high productivity is maintained by adopting such alignment procedures.

Still another merit of the present invention is that optimum results are obtained when the multichamber substrate processing apparatus is an apparatus for depositing thin films on substrates.

An additional merit of the present invention is that the heating chambers are made less bulky and the structure of the rotational structure is simplified.

A further merit of the present invention is that productivity is markedly improved by a dramatic improvement in the efficiency with which the autoloader transfers substrates.

Although only preferred embodiments are specifically illustrated and described herein, it will be appreciated that many modifications and variations of the present invention are possible in light of the above teachings and within the purview of the appended claims without departing from the spirit and intended scope of the invention.

What is claimed is:

1. A multichamber substrate processing apparatus, comprising:
a centrally located separation chamber;
a plurality of process chambers connected to the separation chamber;
a load lock chamber connected to the separation chamber;
a transfer robot in the separation chamber for sequentially transferring a substrate to the plurality of process chambers for treatment in the process chambers;
an alignment means, disposed inside one of the plurality of process chambers, for calculating a center position of the substrate before it is transferred to a second one of the plurality of process chambers in which the substrate is treated while it is centered over a preset position.

2. The apparatus of claim 1, wherein the alignment means includes means for performing circumferential alignment whereby a circumferential position of the substrate is calculated, and the position of the substrate in the circumferential direction is aligned with a preset position.

3. The apparatus of claim 1, wherein the one process chamber is not the process chamber requiring a longest time for processing a single substrate.

4. The apparatus of claim 1, wherein the one process chamber is a heating chamber for heating the substrate to a prescribed temperature prior to deposition of a thin film on the substrate in the second process chambers.

5. The apparatus of claim 4, wherein the second process chamber is a sputtering chamber.

6. The apparatus of claim 4, wherein the second process chamber is a CVD chamber.

7. The apparatus of claim 4, wherein the heating chamber includes a substrate holder that is provided with a built-in heater for heating the substrate when the substrate is placed on the substrate holder.

8. The apparatus of claim 7, wherein the alignment means includes:
a stage for supporting the substrate;
a rotating mechanism for rotating the stage;
a lifting mechanism for lifting the stage; and
a depression formed in an upper surface of the substrate holder, the depression being of sufficient size to accommodate the stage.

9. The apparatus of claim 8, wherein the lifting mechanism includes means for lifting the stage to a position corresponding to a detection line during alignment and for lowering the stage for substrate heating.

10. The apparatus of claim 1, further comprising an autoloader for transferring the substrate between an external cassette disposed on an atmosphere side and in-lock cassettes disposed inside the load lock chamber.

11. The apparatus of claim 10, wherein the autoloader includes means for holding a plurality of substrates together and simultaneously transporting them.
